(19) United States
(12) Patent Application Publication
(10) Pub. No.: US 2024/0030314 A1
(43) Pub. Date: Jan. 25, 2024

(54) SEMICONDUCTOR DEVICE AND METHOD OF MANUFACTURING THE SAME

(71) Applicant: Samsung Electronics Co., Ltd., Suwon-si (KR)

(72) Inventors: Seungmin SONG, Suwon-si (KR); Bongsoo Kim, Suwon-si (KR); Soojin Jeong, Suwon-si (KR)

(73) Assignee: Samsung Electronics Co., Ltd., Suwon-si (KR)

(21) Appl. No.: 18/175,176

(22) Filed: Feb. 27, 2023

(30) Foreign Application Priority Data
Jul. 21, 2022 (KR) 10-2022-0090386

(51) Int. Cl. H01L 29/66; H01L 29/40; H01L 21/311; H01L 21/3115; H01L 29/08; H01L 21/02; H01L 29/423

(52) U.S. Cl. CPC H01L 29/6656; H01L 29/401; H01L 21/311; H01L 21/31155; H01L 29/0847; H01L 21/02107; H01L 29/42364

(57) ABSTRACT

A semiconductor device includes a substrate including an active pattern, a pair of channel patterns spaced apart from each other in a first direction on the active pattern, each of the pair of channel patterns including vertically stacked semiconductor patterns, a source/drain pattern between the pair of channel patterns, a pair of gate electrodes on the channel patterns, an active contact between the pair of gate electrodes, and outer spacers on side surfaces of the pair of gate electrodes. A distance between the outer spacers spaced apart from each other with the active contact therebetween is smaller than a width of the source/drain pattern in the first direction at a first level at which an upper surface of an uppermost semiconductor pattern among the semiconductor patterns is positioned.

### CROSS-REFERENCE TO RELATED APPLICATIONS

This U.S. non-provisional patent application claims priority under 35 U.S.C.§119 to Korean Patent Application No. 10-2022-0090386, filed on Jul. 21, 2022, in the Korean Intellectual Property Office, the entire contents of which are hereby incorporated by reference.

### BACKGROUND

Inventive concepts relate to a semiconductor device and/or a method for manufacturing the same, and more particularly, relates to a semiconductor device including a field effect transistor and/or a method for manufacturing the same.

A semiconductor device may include an integrated circuit consisting of or including metal-oxide-semiconductor field-effect transistors (MOS-FETs). To meet or at least partially meet increasing demand for a semiconductor device with a small pattern size and/or a reduced design rule, MOS-FETs are being aggressively scaled down. The scale-down of MOS-FETs may lead to deterioration in operational properties of a semiconductor device. A variety of studies are being conducted to overcome technical limitations associated with the scale-down of semiconductor devices and/or to realize high-performance semiconductor devices.

### SUMMARY

At least one object example embodiments is to provide a semiconductor device with improved electrical characteristics and reliability, and/or a method for manufacturing the same.

Problems to be solved by example embodiments are not limited to the above-mentioned problems, and other problems not mentioned will be clearly understood by those of ordinary skill in the art from the following description.

A semiconductor device according to various example embodiments may include a substrate including an active pattern, a pair of channel patterns spaced apart from each other in a first direction on the active pattern, each of the pair of channel patterns including vertically stacked semiconductor patterns, a source/drain pattern between the pair of channel patterns, a pair of gate electrodes on the pair of channel patterns, an active contact between the pair of gate electrodes, and outer spacers on side surfaces of the pair of gate electrodes. A distance between the outer spacers spaced apart from each other with the active contact therebetween may be smaller than a width of the source/drain pattern in the first direction at a first level at which an upper surface of an uppermost semiconductor pattern among the semiconductor patterns is positioned.

A semiconductor device according to various example embodiments may include a substrate including an active pattern, an isolation pattern surrounding the active pattern, a pair of channel patterns spaced apart from each other in a first direction on the active pattern, each of the pair of channel patterns including vertically stacked semiconductor patterns, a source/drain pattern between the pair of channel patterns, a pair of gate electrodes on the pair of channel patterns, gate capping patterns on upper surfaces of the pair of gate electrodes, an interlayer insulating layer between the pair of gate electrodes, outer spacers on side surfaces of the pair of gate electrodes, inner spacers between the side surfaces of the pair of gate electrodes and the outer spacers, gate insulating patterns between the pair of gate electrodes and the inner spacers, and an active contact connected to the source/drain pattern through the interlayer insulating layer. The outer spacers and the inner spacers may extend on side surfaces of the gate capping patterns. A distance between the outer spacers spaced apart from each other with the active contact therebetween may be smaller than a width of a source/drain pattern in the first direction at a first level at which an upper surface of an uppermost semiconductor pattern among the semiconductor patterns is positioned.

A method of manufacturing a semiconductor device according to various example embodiments may include forming a stacked pattern on a substrate, forming sacrificial patterns on the stacked pattern, hard mask patterns on upper surfaces of the sacrificial patterns, and mask recesses between the sacrificial patterns, performing an ion implantation process after forming an inner spacer layer conformally covering inner walls of the mask recesses, forming an outer spacer layer conformally covering the inner spacer layer, etching the inner spacer layer and the outer spacer layer to form inner spacers and outer spacers, respectively, etching the stacked pattern using the hard mask patterns, the inner spacers, and the outer spacers as an etch mask to form a recess, and forming a source/drain pattern filling the recess.

### BRIEF DESCRIPTION OF THE DRAWINGS

Various example embodiments will be more clearly understood from the following brief description taken in conjunction with the accompanying drawings. The accompanying drawings represent non-limiting, example embodiments as described herein.

FIG. 1 is a plan view of a semiconductor device according to various example embodiments.

FIGS. 2A to 2D are cross-sectional views corresponding to lines A-A′, B-B′, C-C′, and D-D′ of FIG. 1, respectively.

FIGS. 3A and 3B are views corresponding to a portion “P1” of FIG. 1, and are enlarged views at a first level.

FIGS. 4A to 8B are enlarged views corresponding to a portion “P2” of FIG. 2 and a portion “P3” of FIG. 3.

FIGS. 9A to 14C are cross-sectional views illustrating a method of manufacturing a semiconductor device according to various example embodiments.

### DETAILED DESCRIPTION

Hereinafter, a semiconductor device according to various example embodiments will be described in detail with reference to the drawings.

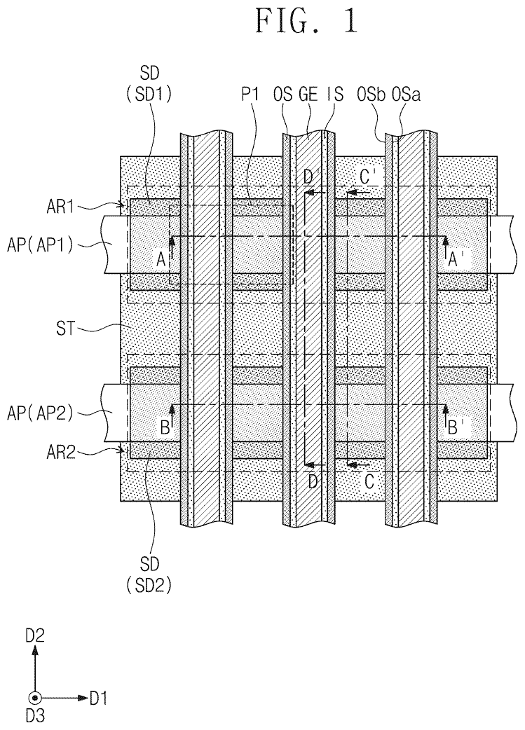

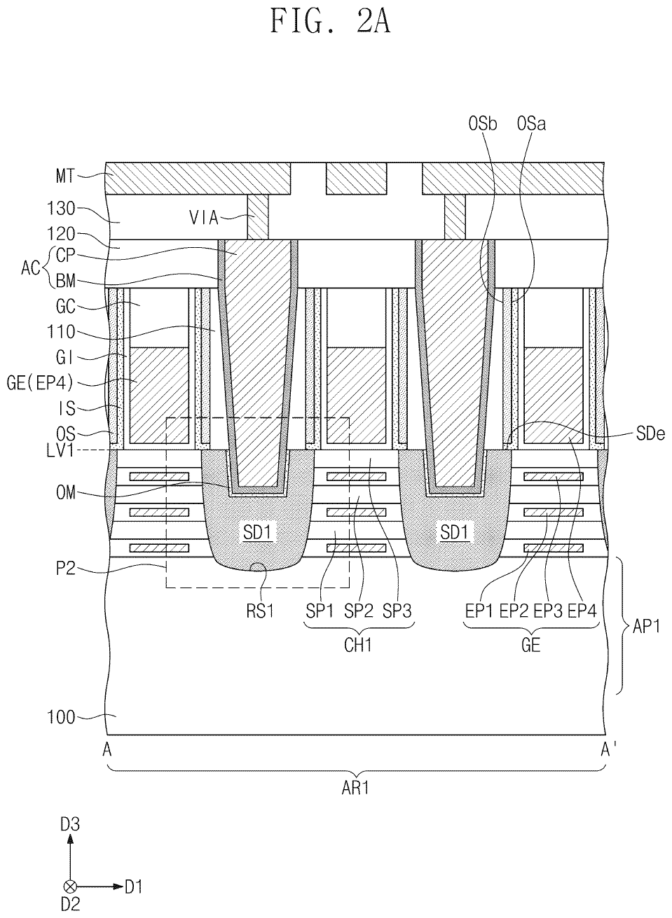

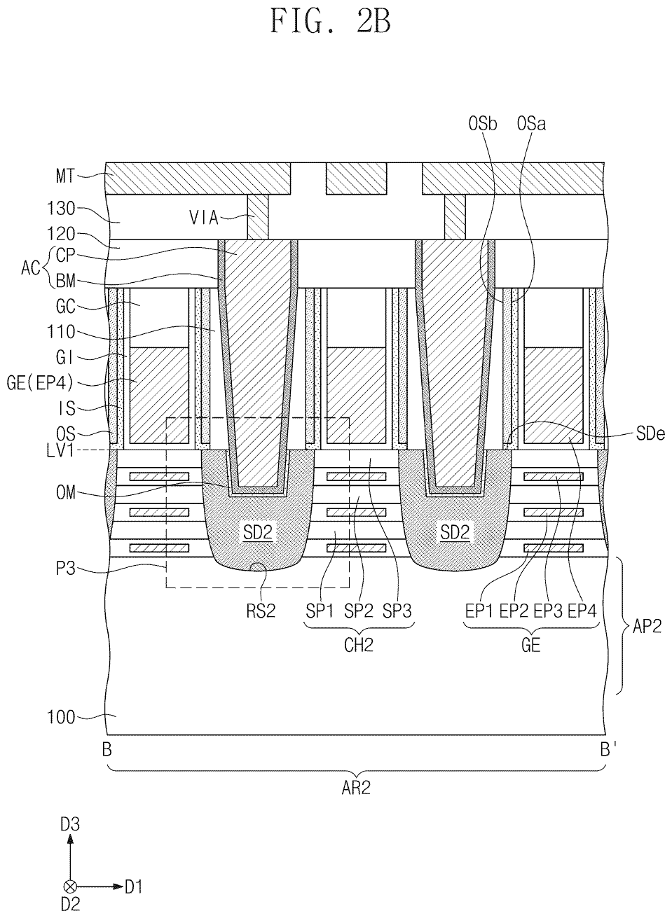

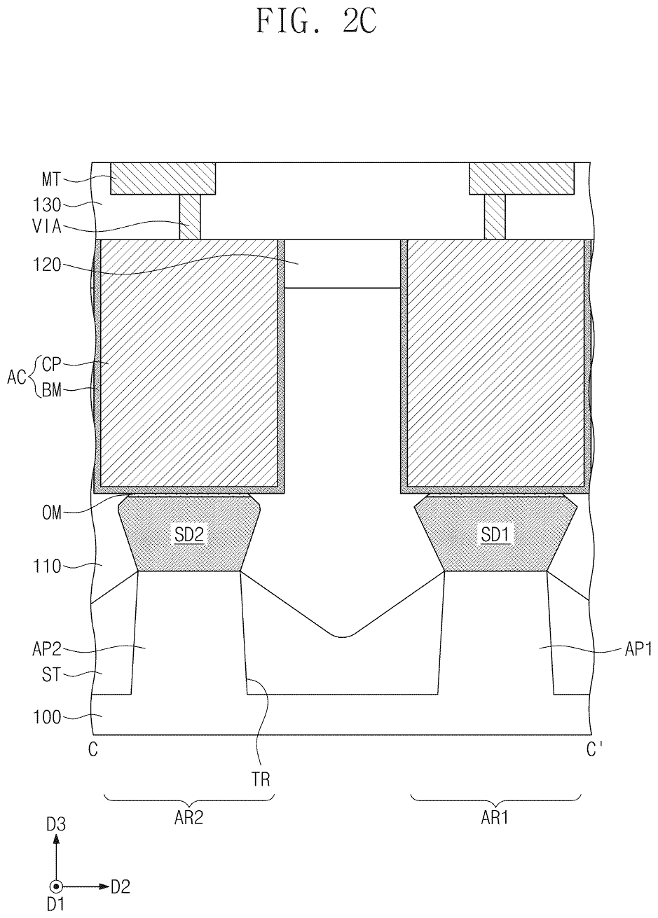

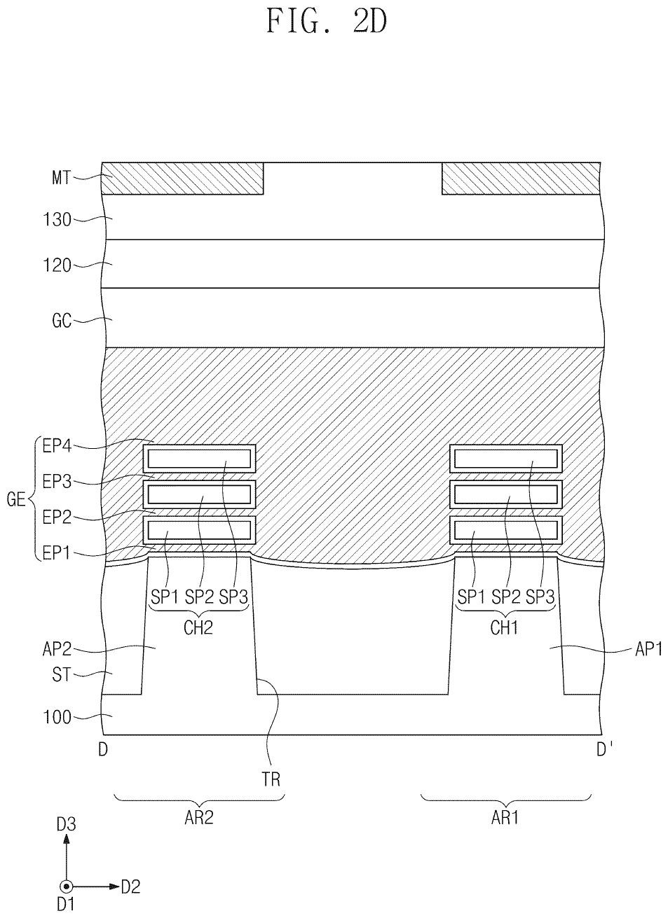

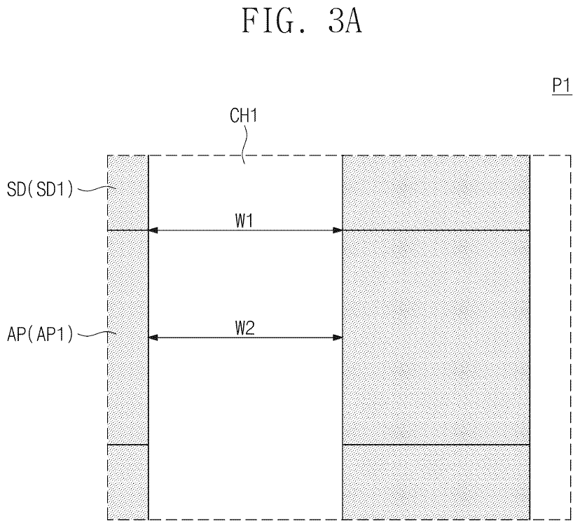

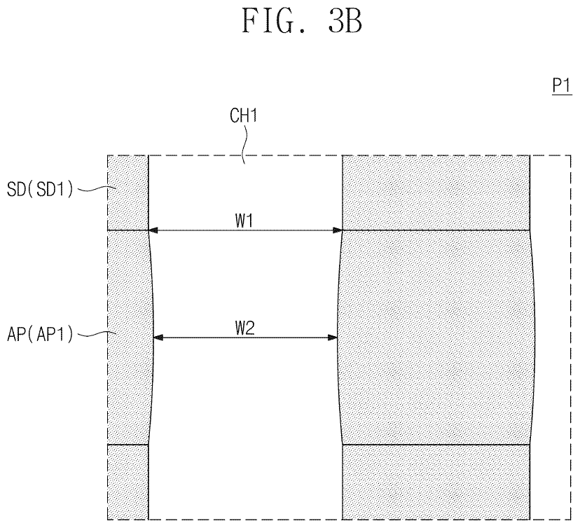

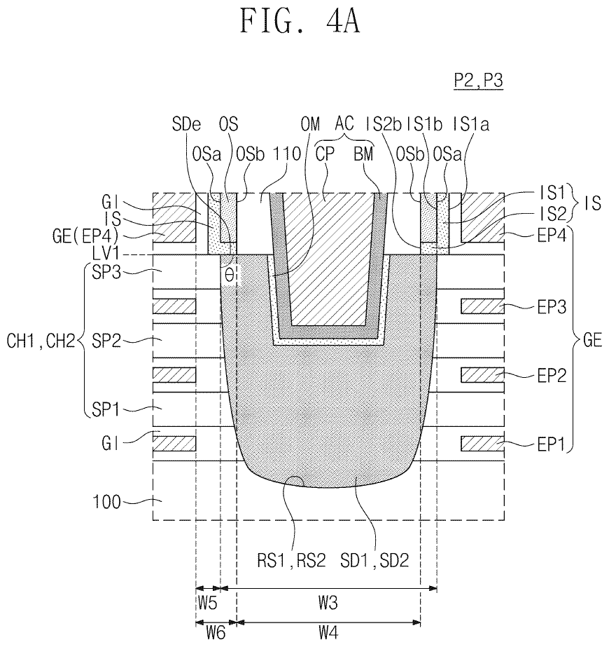

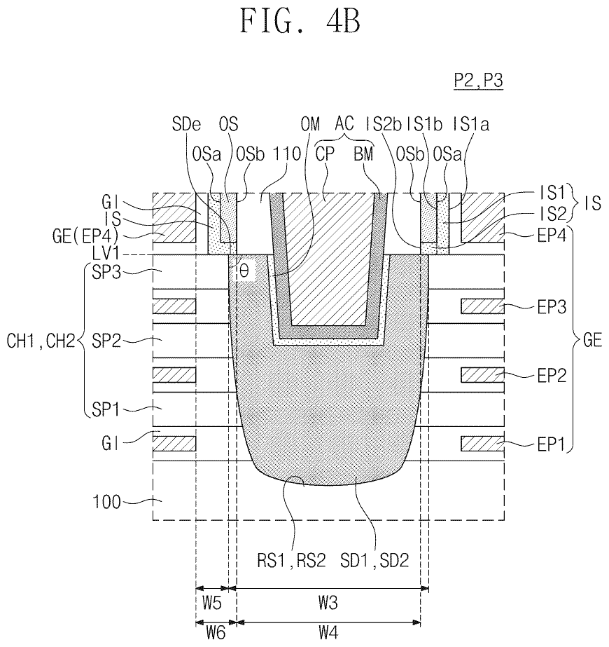

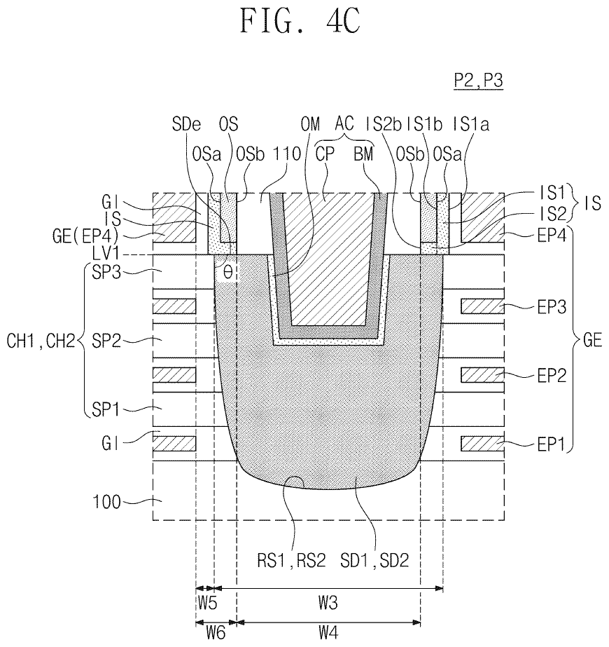

FIG. 1 is a plan view of a semiconductor device according to various example embodiments. FIGS. 2A to 2D are cross-sectional views corresponding to lines A-A′, B-B′, C-C′, and D-D′ of FIG. 1, respectively. FIGS. 3A and 3B are views corresponding to a portion “P1” of FIG. 1, and are enlarged views at a first level. FIGS. 4A to 8B are enlarged views corresponding to a portion “P2” of FIG. 2 and a portion “P3” of FIG. 3.

Referring to FIGS. 1 and 2A to 2D, a substrate 100 including a first active region AR1 and a second active region AR2 may be provided. The first and second active regions AR1 and AR2 may extend in a first direction D1 and may be spaced apart from each other in a second direction D2. The first and second directions D1 and D2 may be parallel to a lower surface of the substrate 100 and may intersect (e.g., perpendicular) to each other. The substrate 100 may be or may include a semiconductor substrate including one or more of silicon, germanium, silicon-germanium, or so forth, or a compound semiconductor substrate. For example, the substrate 100 may be or may include a silicon substrate. In some example embodiments, the substrate 100 may be doped, e.g., may be lightly doped with impurities; however, example embodiments are not limited thereto. For example, the first active region AR1 may be a PMOSPET region, and the second active region AR2 may be an NMOSFET region.

An active pattern AP may be defined by a trench TR in an upper portion of the substrate 100. The active pattern AP may include a first active pattern AP1 and a second active pattern AP2. The first active pattern AP1 may be provided on the first active region AR1, and the second active pattern AP2 may be provided on the second active region AR2. The first and second active patterns AP1 and AP2 may extend in the second direction D2. The first and second active patterns AP1 and AP2 may be or may include a portion of the substrate 100, for example, a portion of the substrate 100 protruding in a third direction D3. The third direction D3 may be a direction perpendicular to the lower surface of the substrate 100.

A device isolation pattern ST may fill the trench TR. The device isolation pattern ST may surround the first and second active patterns AP1 and AP2. The device isolation pattern ST may include, for example, silicon oxide. The device isolation pattern ST may not cover first and second channel patterns CH1 and CH2, which will be described later.

The first channel pattern CH1 may be provided on the first active pattern AP1, and the second channel pattern CH2 may be provided on the second active pattern AP2. The first channel pattern CH1 may be provided in plurality and the first channel patterns CH1 may be spaced apart from each other in the first direction D1. The second channel pattern CH2 may be provided in plurality and the second channel patterns CH2 may be spaced apart from each other in the first direction D1. Each of the first and second channel patterns CH1 and CH2 may include a first semiconductor pattern SP1, a second semiconductor pattern SP2, and a third semiconductor pattern SP3 that are sequentially stacked. However, example embodiments are not limited thereto, and as an example, each of the first and second channel patterns CH1 and CH2 may include two, four or more semiconductor patterns. The first to third semiconductor patterns SP1, SP2, and SP3 may be spaced apart from each other in the third direction D3. Each of the first to third semiconductor patterns SP1, SP2, and SP3 may include crystalline silicon, such as polycrystalline or single crystalline silicon.

Referring to FIGS. 2A, 3A and 3B, an upper surface of the first channel pattern CH1 may extend in the second direction D2 a first level LV1. Although features of the first channel pattern CH1 will be described below, this is for convenience of description, and substantially the same features may be applied to the second channel pattern CH2 as well.

For example, as illustrated in FIG. 3A, the upper surface of the first channel pattern CH1 may extend in the second direction D2 and may maintain substantially the same width in the first direction D1. In this case, a first width W1 of the first channel pattern CH1 on one end of the first active pattern AP1 in the second direction D2 may be substantially identical to a second width W2 of the first channel pattern CH1 on a point having the same distance from both ends of the first active pattern AP1.

As another example, as shown in FIG. 3B, the upper surface of the first channel pattern CH1 may have a concave profile in the first direction D1 and may extend in the second direction D2. In this case, the first width W1 of the first channel pattern CH1 may be greater than the second width W2.

Referring back to FIGS. 1 and 2A to 2D, a first source/drain pattern SD1 may be provided on the first active pattern AP1. The first source/drain pattern SD1 may be provided in plurality, and the first source/drain patterns SD1 may be provided between first channel patterns CH1 adjacent to each other in the first direction D1. The first source/drain patterns SD1 may fill or at least partially first recesses RS1 provided between the first channel patterns CH1, respectively. A pair of first source/drain patterns SD1 may be disposed on both side surfaces of one first channel pattern CH1, and the first to third semiconductor patterns SP1, SP2, and SP3 of the first channel pattern CH1 may connect the pair of first source/drain patterns SD1 to each other. The first source/drain patterns SD1 may be impurity regions having a first conductivity type (e.g., p-type), and in some example embodiments, may be doped with an impurity such as boron.

A second source/drain pattern SD2 may be provided on the second active pattern AP2. The second source/drain pattern SD2 may be provided in plurality, the second source/drain pattern SD2 and may be provided between second channel patterns CH2 adjacent to each other in the first direction D1. The second source/drain patterns SD2 may fill second recesses RS2 provided between the second channel patterns CH2, respectively. A pair of second source/drain patterns SD2 may be disposed on both side surfaces of one second channel pattern CH2, and the first to third semiconductor patterns SP1, SP2, and SP3 of the second channel pattern CH2 may connect the pair of second source/drain patterns SD2 to each other. The second source/drain patterns SD2 may be impurity regions having a second conductivity type (e.g., n-type), and may be doped with impurities such as arsenic and/or phosphorus.

The first and second source/drain patterns SD1 and SD2 may include epitaxial patterns, which may be patterns corresponding to or formed by a selective epitaxial growth (SEG) process. For example, an upper surface of each of the first and second source/drain patterns SD1 and SD2 may be positioned at a level higher than an upper surface of the third semiconductor pattern SP3. As another example, an upper surface of at least one of the first and second source/drain patterns SD1 and SD2 may be positioned at substantially the same level as an upper surface of the third semiconductor pattern SP3. There may be a seam and/or an interface between either or both of the first and second source/drain patterns SD1 and SD22 in connection with either or both of the first and second active patterns AP1 and AP2.

In various example embodiments, the first source/drain patterns SD1 may include a semiconductor element (e.g., SiGe) having a lattice constant greater than a lattice constant of a semiconductor element of the substrate 100. Accordingly, the pair of first source/drain patterns SD1 may provide a compressive stress to the first channel pattern CH1 therebetween. The second source/drain patterns SD2 may include the same semiconductor element (e.g., Si) as the substrate 100, and/or may not include germanium (Ge).

A gate electrode GE may cross the first and second channel patterns CH1 and CH2. The gate electrode GE may be provided in plurality. The gate electrodes GE may extend in the second direction D2 and may be spaced apart from each other in the first direction D1. The gate electrode GE may vertically overlap the first and second channel patterns CH1 and CH2.

For example, the gate electrode GE may include a first electrode part EP1, a second electrode part EP2, a third electrode part EP3, and a fourth electrode part EP4. The first electrode part EP1 may be interposed between the active pattern AP and the first semiconductor pattern SP1. The second electrode part EP2 may be interposed between the first semiconductor pattern SP1 and the second semiconductor pattern SP2. The third electrode part EP3 may be interposed between the second semiconductor pattern SP2 and the third semiconductor pattern SP3. The fourth electrode part EP4 may be provided on the third semiconductor pattern SP3.

The gate electrode GE may include a first metal pattern and a second metal pattern on the first metal pattern. The first metal pattern may be provided on a gate insulating pattern GI to be described later and may be adjacent to the first to third semiconductor patterns SP1, SP2, and SP3. The first metal pattern may include a work function metal that adjusts a threshold voltage of the transistor. A threshold, such as a desired threshold voltage of the transistor may be achieved by adjusting a thickness and/or a composition of the first metal pattern. For example, the first to third electrode parts EP1, EP2, and EP3 of the gate electrode GE may be formed of the first metal pattern that is the work function metal.

The first metal pattern may include a metal nitride layer. For example, the first metal pattern may include nitrogen (N) and at least one metal selected from among, or from the group consisting of titanium (Ti), tantalum (Ta), aluminum (Al), tungsten (W), and molybdenum (Mo). Furthermore, the first metal pattern may further include carbon (C). The first metal pattern may include a plurality of stacked work function metals.

The second metal pattern may include a metal having a lower resistance than a resistance of the first metal pattern. For example, the second metal pattern may include at least one metal selected from among, or from the group consisting of tungsten (W), aluminum (Al), titanium (Ti), and tantalum (Ta). For example, the fourth electrode part EP4 of the gate electrode GE may include the first metal pattern and the second metal pattern on the first metal pattern.

A gate capping pattern GC may be provided on an upper surface of the gate electrode GE. The gate capping pattern GC may extend in the second direction D2 along the gate electrode GE. The gate capping pattern GC may include a material having etch selectivity with respect to first and second interlayer insulating layers 110 and 120 to be described later. For example, the gate capping pattern GC may include at least one of SiON, SiCN, SiOCN, and SiN.

Inner spacers IS may be provided on side surfaces of the fourth electrode part EP4 of the gate electrode GE and may extend on side surfaces of the gate capping pattern GC. The inner spacers IS may extend in the second direction D2 along the gate electrode GE. Upper surfaces of the inner spacers IS may be positioned at a level higher than an upper surface of the gate electrode GE, and may be substantially coplanar with an upper surface of the gate capping pattern GC. For example, the inner spacers IS may include at least one of SiON, SiCN, SiOCN, and SiN. Alternatively or additionally, the inner spacers IS may further include germanium (Ge) ions.

Outer spacers OS may be provided on side surfaces of the inner spacers IS and may extend on the side surfaces of the gate capping pattern GC. The outer spacers OS may extend in the second direction D2 along the inner spacers IS. Upper surfaces of the outer spacers OS may be positioned at a level higher than the upper surface of the gate electrode GE, and may be substantially coplanar with the upper surfaces of the inner spacers IS. Each of the inner spacers IS may be disposed between the side surface of the fourth electrode part EP4 and the outer spacer OS. For example, the outer spacers OS may include at least one of SiON, SiCN, SiOCN, and SiN.

Hereinafter, features of the first and second source/drain patterns SD1 and SD2, the inner spacers IS, and the outer spacers OS will be described in more detail with reference to FIGS. 4A to 8B.

Referring to FIGS. 4A to 8B, each of the inner spacers IS may include an extension part IS1 extending in the third direction D3 on the side surface of the fourth electrode part EP4, and a corner part IS2 protruding from a lower portion of the extension part IS1 in the first direction D1. Accordingly, the inner spacers IS may have an L-shape, when viewed in a cross-section. The extension part IS1 may include an inner surface IS1a opposite to the fourth electrode part EP4 and an outer surface IS1b opposite to the inner surface IS1a. The inner surface IS1a of the extension part IS1 may be in contact with, e.g. in direct contact with, a gate insulating pattern GI to be described later. The corner part IS2 may include an outer surface IS2b opposite to the inner surface IS1a of the extension part IS1.

Each of the outer spacers OS may be provided on an upper surface of the corner part IS2 of each of the inner spacers IS and may extend in the third direction D3 along the extension part IS1 of each of the inner spacers IS. The outer spacer OS may be in contact with the upper surface of the corner part IS2 and the outer surface IS1b of the extension part IS1. The outer spacer OS may include an inner surface OSa in contact with the outer surface IS1b of the extension part IS1 and an outer surface OSb opposite to the inner surface OSa. The outer surface OSb of the outer spacer OS may be vertically aligned with the outer surface IS2b of the corner part IS2.

The first and second source/drain patterns SD1 and SD2 may have a third width W3 in the first direction D1 at the first level LV1. The first level LV1 may be or may correspond to a level at which an upper surface of an uppermost semiconductor pattern (e.g., the third semiconductor pattern SP3) among the semiconductor patterns (e.g., the first to third semiconductor patterns SP1, SP2, and SP3) is positioned. The third width W3 may be greater than a distance W4 between the outer spacers OS spaced apart with an active contact AC to be described interposed therebetween. A portion of the first and second source/drain patterns SD1 and SD2 may vertically overlap the outer spacers OS and the corner parts IS2 of the inner spacers IS. The corner parts IS2 of the inner spacers IS may extend between lower surfaces of the outer spacers OS and the first and second source/drain patterns SD1 and SD2. The source/drain patterns SD1 and SD2 may be vertically spaced apart from the outer spacers OS by the inner spacers IS.

The first and second source/drain patterns SD1 and SD2 may be in contact with, e.g. in direct contact with, the inner spacers IS. Upper surfaces of the first and second source/drain patterns SD1 and SD2 may include edge surfaces SDe, and the edge surfaces SDe may be defined as regions of upper surfaces of the first and second source/drain patterns SD1 and SD2 in contact with lower surfaces of the inner spacers IS. A distance W5 from an end of each of the edge surfaces SDe to an extension line of a side surface of the fourth electrode part EP4 may be smaller than a distance W6 from the outer surface OSb of the outer spacer OS to the side surface of the fourth electrode part EP4. The edge surfaces SDe may be positioned at the first level LV1, and for example, may be substantially coplanar with the uppermost semiconductor pattern (e.g., the third semiconductor pattern SP3). The edge surfaces SDe may be provided under the inner and outer spacers IS and OS, and may be spaced apart from the outer spacers OS by corner parts IS2 of the inner spacers IS.

For example, as shown in FIG. 4A, the edge surfaces SDe may be in contact with the corner parts IS2 of the inner spacers IS. The edge surfaces SDe may completely cover lower surfaces of the corner parts IS2. The edge surfaces SDe may vertically overlap the outer spacers OS and the corner parts IS2 of the inner spacers IS. The edge surfaces SDe may not be in contact with the extension parts IS1 of the inner spacers IS. The third width W3 may be substantially equal to a distance between the inner surfaces OSa of the outer spacers OS spaced apart with an active contact AC to be described, interposed therebetween.

Alternatively or additionally, as shown in FIG. 4B, the edge surfaces SDe may be in contact with the corner parts IS2 of the inner spacers IS. The edge surfaces SDe may cover, or at least partially cover, a portion of lower surfaces of the corner parts IS2. Other portions of lower surfaces of the corner parts IS2 may be in contact with the uppermost semiconductor pattern (e.g., the third semiconductor pattern SP3). The edge surfaces SDe may vertically overlap the outer spacers OS and the corner parts IS2 of the inner spacers IS. The edge surfaces SDe may not be in contact with the extension parts IS1 of the inner spacers IS. The third width W3 may be smaller than the distance between the inner surfaces OSa of the outer spacers OS spaced apart with the active contact AC to be described, interposed therebetween.

Alternatively or additionally, as shown in FIG. 4C, the edge surfaces SDe may be in contact with the corner parts IS2 and the extension parts IS1 of the inner spacers IS. The edge surfaces SDe may completely cover lower surfaces of the corner parts IS2, and may cover at least a portion of lower surfaces of the extension parts IS1. The edge surfaces SDe may vertically overlap at least some of the outer spacers OS and the corner parts IS2 and the extension parts IS1 of the inner spacers IS. The third width W3 may be greater than the distance between the inner surfaces OSa of the outer spacers OS spaced apart with the active contact AC to be described, interposed therebetween.

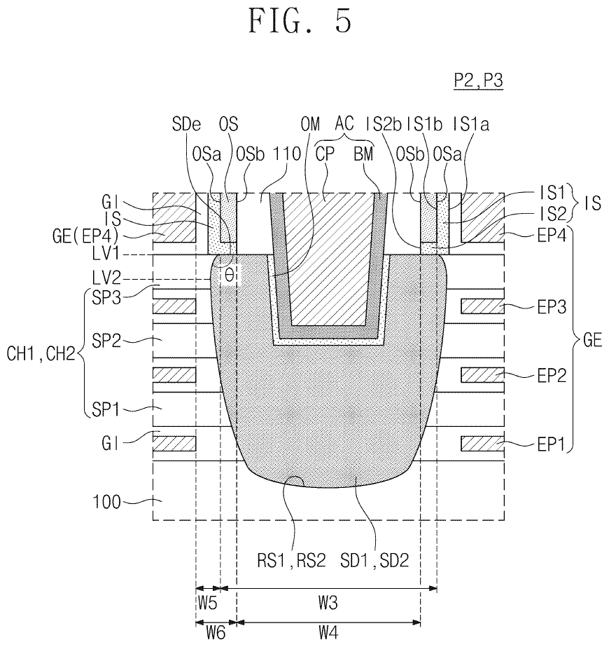

Referring to FIGS. 4A to 4C and 5, widths of the first and second source/drain patterns SD1 and SD2 may vary in the first direction D1 depending on levels. For example, as shown in FIGS. 4A to 4C, the widths of the first and second source/drain patterns SD1 and SD2 may be greater than other levels, e.g. may be maximum at the first level LV1. In this case, an angle θ between the edge surfaces SDe and the side surfaces of the first and second source/drain patterns SD1 and SD2 may be less than or equal to 90 degrees. As another example, as shown in FIG. 5, widths of the first and second source/drain patterns SD1 and SD2 may be greater than other levels, e.g. may be maximum at a second level LV2. In this case, the second level LV2 may be positioned between an upper surface and a lower surface of an uppermost semiconductor pattern (e.g., the third semiconductor pattern SP3). In this case, the angle θ between the edge surfaces SDe and the side surfaces of the first and second source/drain patterns SD1 and SD2 may be greater than 90 degrees. However, example embodiments are not limited thereto. In some example embodiments , a width of the first and second source/drain patterns SD1 and SD2 may be greater than other levels, e.g. may have a maximum at a level other than the first and second levels LV1 and LV2.

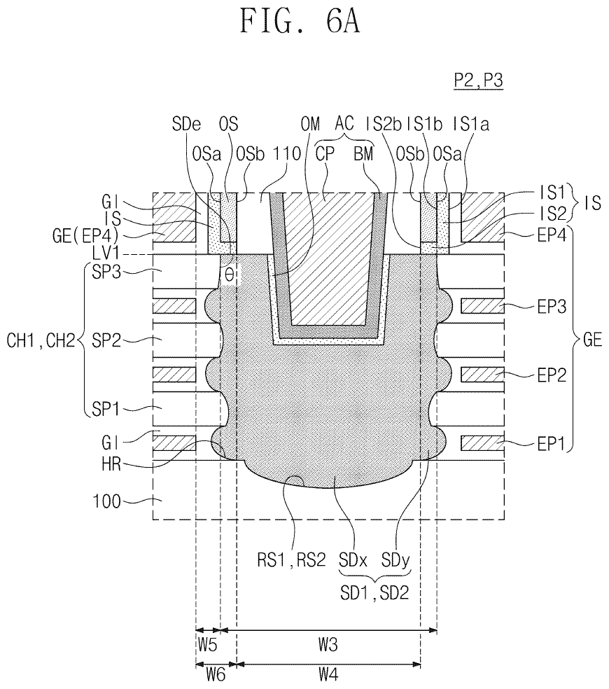

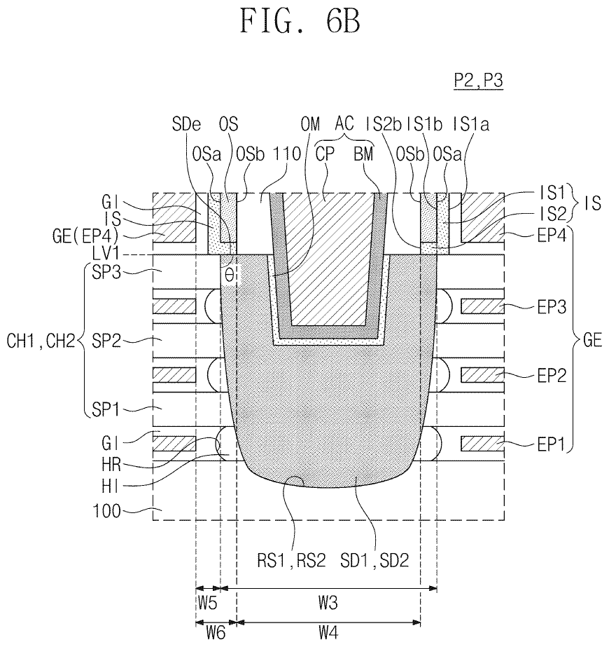

Referring to FIGS. 6A and 6B, horizontal recesses HR recessed in the first direction D1 from the first and second recesses RS1 and RS2 may be provided. The horizontal recesses HR may be regions recessed in the first direction D1 toward the first to third electrode parts EP1, EP2, and EP3.

For example, as shown in FIG. 6A, the first and second source/drain patterns SD1 and SD2 may fill the horizontal recesses HR. Each of the first and second source/drain patterns SD1 and SD2 may have a filling part SDx filling the first and second recesses RS1 and RS2 and protrusions SDy filling the horizontal recesses HR, respectively. The protrusions SDy may be portions of the first and second source/drain patterns SD1 and SD2 protruding from the filling part SDx in the first direction D1 toward the first to third electrode parts EP1, EP2, and EP3 of the gate electrode GE. The protrusions SDy may be interposed between the first to third semiconductor patterns SP, SP2, and SP3. Due to the protrusions SDy, side surfaces of each of the first and second source/drain patterns SD1 and SD2 may have an embossed, e.g., a rough embossed shape. For example, a side surface of each of the first and second source/drain patterns SD1 and SD2 may have a wavy profile. For example, a side surface of each of the first and second source/drain patterns SD1 and SD2 may be further protrude than the side surfaces of the first to third semiconductor patterns SP1, SP2, and SP3 from the first to third electrode parts EP1, EP2, and EP3 in the first direction D1.

Alternatively or additionally, as shown in FIG. 6B, horizontal insulating patterns HI may fill the horizontal recesses HR. The horizontal insulating patterns HI may be interposed between the first and second source/drain patterns SD1 and SD2 and the first to third electrode parts EP1, EP2, and EP3 of the gate electrode GE. The horizontal insulating patterns HI may be interposed between the first to third semiconductor patterns SP1, SP2, and SP3. The horizontal insulating patterns HI may separate the gate electrode GE from the first source/drain pattern SD1, and/or the gate electrode GE from the second source/drain pattern SD2. In some example embodiments, the horizontal insulating patterns HI may reduce, or may help to reduce, leakage current from the gate electrode GE. The horizontal insulating patterns HI may include, for example, at least one of silicon oxide, silicon oxynitride, and silicon nitride.

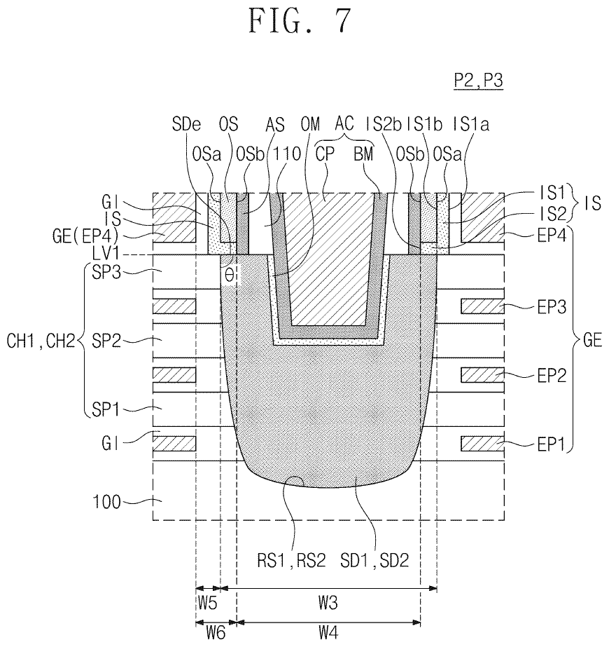

Referring to FIG. 7, an auxiliary spacer AS may be provided on each of the outer surfaces OSb of the outer spacers OS. The auxiliary spacers AS may cover the outer surfaces OSb of the outer spacers OS and the outer surfaces IS2b of the corner parts IS2 of the inner spacers IS, and may extend in the third direction D3. The auxiliary spacers AS may be provided on upper surfaces of the first and second source/drain patterns SD1 and SD2, and for example, may be in contact with the upper surfaces of the first and second source/drain patterns SD1 and SD2. Lower surfaces of the auxiliary spacers AS may be substantially coplanar with lower surfaces of the inner spacers IS. The auxiliary spacers AS may include, for example, at least one of SiON, SiCN, SiOCN, and SiN.

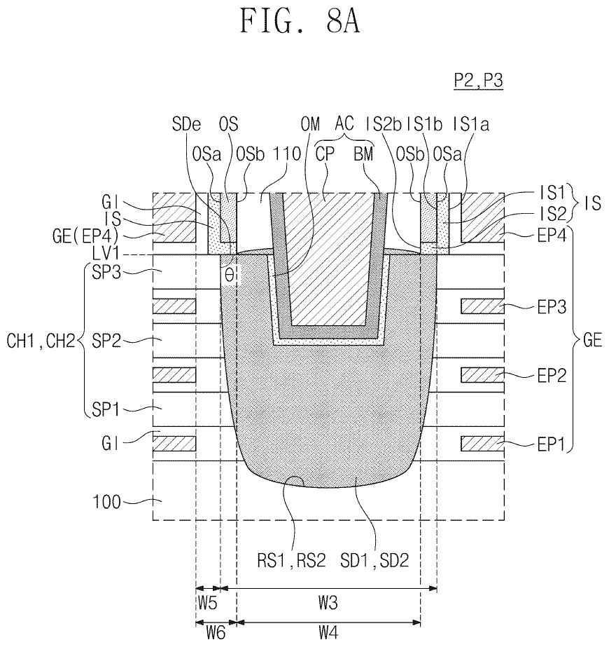

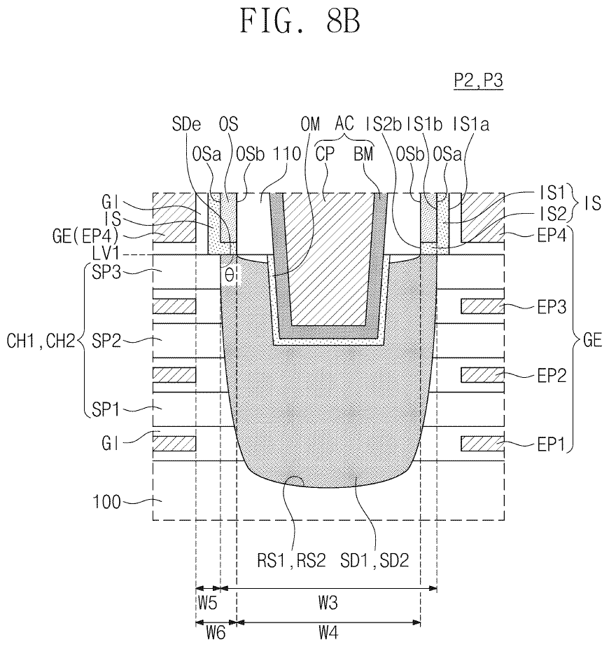

Referring to FIGS. 8A and 8B, upper surfaces of the first and second source/drain patterns SD1 and SD2 may not be flat.

For example, as shown in FIG. 8A, the upper surfaces of the first and second source/drain patterns SD1 and SD2 may have a convex profile. In detail, the edge surfaces SDe among the upper surfaces of the first and second source/drain patterns SD1 and SD2 may have a substantially flat profile at both side surfaces of the first and second source/drain patterns SD1 and SD2. The other portion of the upper surfaces of the first and second source/drain patterns SD1 and SD2 may have the convex profile between the edge surfaces SDe. The other portion may have the convex profile at a level substantially equal to or higher than the first level LV1.

Alternatively or additionally, as shown in FIG. 8B, the upper surfaces of the first and second source/drain patterns SD1 and SD2 may have a concave profile. In detail, the edge surfaces SDe among the upper surfaces of the first and second source/drain patterns SD1 and SD2 may have a substantially flat profile at both side surfaces of the first and second source/drain patterns SD1 and SD2. The other portion of upper surfaces of the first and second source/drain patterns SD1 and SD2 may have the concave profile between the edge surfaces SDe. The other portion may have the concave profile at a level substantially equal to or lower than the first level LV1.

Referring back to FIGS. 1 and 2A to 2D, the gate insulating pattern GI may be interposed between the gate electrode GE and the first to third semiconductor patterns SP1, SP2, and SP3 (i.e., between the gate electrode GE and the first channel pattern CH1 and between the gate electrode GE and the second channel pattern CH2). The gate insulating pattern GI may cover an upper surface, a lower surface, and both side surfaces of each of the first to third semiconductor patterns SP1, SP2, and SP3. The gate insulating pattern GI may cover an upper surface of the device isolation pattern ST under the gate electrode GE. The gate insulating pattern GI may be interposed between the fourth electrode part EP4 and the inner spacer IS.

In various example embodiments, the gate insulating pattern GI may include one or more of silicon oxide, silicon oxynitride, and/or a high-k layer. For example, the gate insulating pattern GI may have a structure in which silicon oxide and a high dielectric material are stacked. The high-k material may include a high-k material having a higher dielectric constant than a dielectric constant of silicon oxide. For example, the high-k material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

A first interlayer insulating layer 110 may be provided on the substrate 100. The first interlayer insulating layer 110 may cover the outer spacers OS and the first and second source/drain patterns SD1 and SD2. An upper surface of the first interlayer insulating layer 110 may be substantially coplanar with an upper surface of the gate capping pattern GC and upper surfaces of the inner and outer spacers IS and OS.

A second interlayer insulating layer 120 may cover the gate capping pattern GC on the first interlayer insulating layer 110. A third interlayer insulating layer 130 may be provided on the second interlayer insulating layer 120. For example, the first to third interlayer insulating layers 110, 120, and 130 may include silicon oxide.

An active contact AC may pass through the first and second interlayer insulating layers 110 and 120 in the third direction D3. The active contacts AC may be provided in plurality, and each of the active contacts AC may be connected to each of the first and second source/drain patterns SD1 and SD2. A lower portion of each of the active contacts AC may be buried in an upper portion of corresponding source/drain patterns SD1 and SD2. The active contact AC may be disposed between the fourth electrode parts EP4 of the gate electrodes GE. The outer spacers OS may be spaced apart from each other in the first direction D1 with the active contacts AC interposed therebetween. The inner spacers IS may be spaced apart from each other in the first direction D1 with the active contacts AC interposed therebetween.

The active contact AC may include a conductive pattern CP passing through the first and second interlayer insulating layers 110 and 120 and a barrier pattern BM surrounding the conductive pattern CP. For example, the conductive pattern CP may include at least one of aluminum, copper, tungsten, molybdenum, and cobalt. The barrier pattern BM may cover side surfaces and a lower surface of the conductive pattern CP. The barrier pattern BM may include at least one of a metal and a metal nitride. The metal may include at least one of titanium, tantalum, tungsten, nickel, cobalt, and platinum. The metal nitride may include at least one of titanium nitride (TiN), tantalum nitride (TaN), tungsten nitride (WN), nickel nitride (NiN), cobalt nitride (CoN), and platinum nitride (PtN).

An ohmic pattern OM may be interposed between the active contact AC and corresponding source/drain patterns SD1 and SD2. The active contact AC may be electrically connected to corresponding source/drain patterns SD1 and SD2 through the ohmic pattern OM. The ohmic pattern OM may include, for example, at least one of titanium-silicide, tantalum-silicide, tungsten-silicide, nickel-silicide, and cobalt-silicide.

Metal patterns MT may be provided in the third interlayer insulating layer 130. Vias VIA may connect the metal patterns MT to the active contacts AC. Although not shown, gate contacts may be connected to the gate electrodes GE, and the metal patterns MT may be connected to the gate contacts through vias VIA. Although not shown, each of the metal patterns MT and the vias VIA may be provided in a plurality of layers, and each of the metal patterns MT and each of the vias VIA may be alternately stacked. The metal patterns MT and the vias VIA may include at least one metal material selected from aluminum, copper, tungsten, molybdenum, ruthenium, and cobalt.

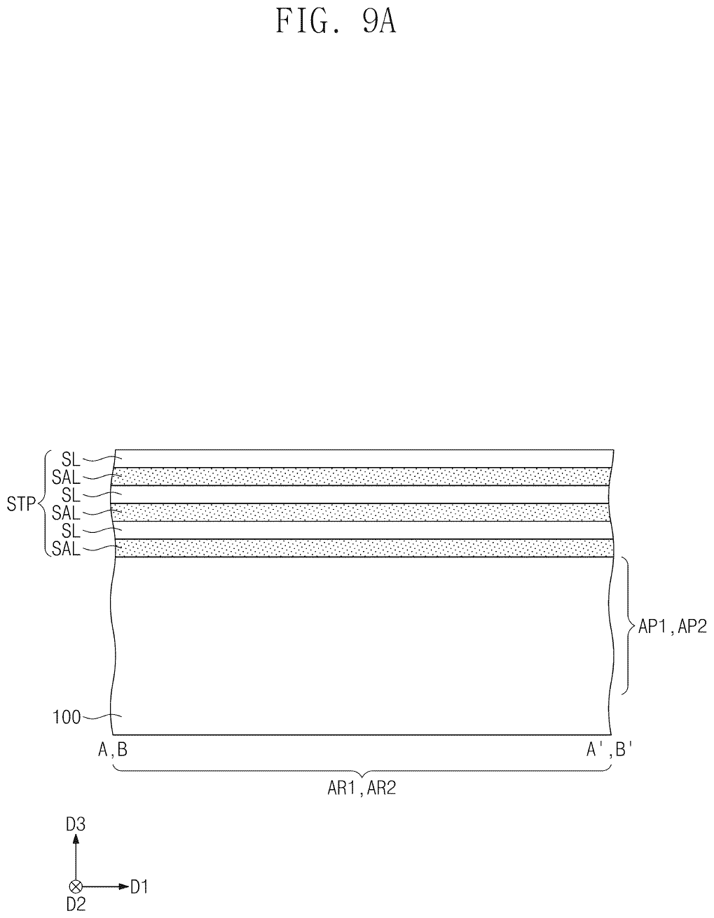

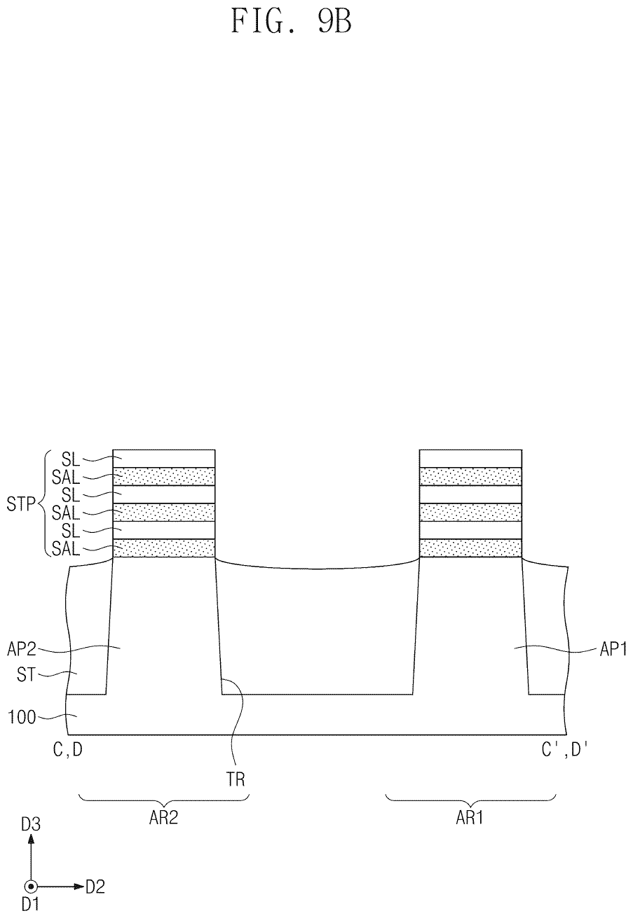

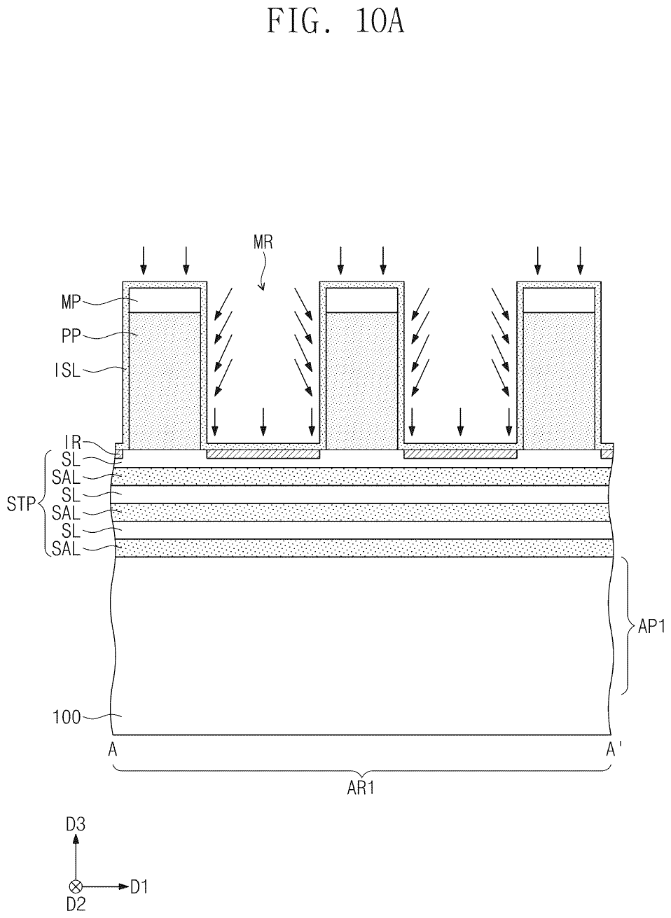

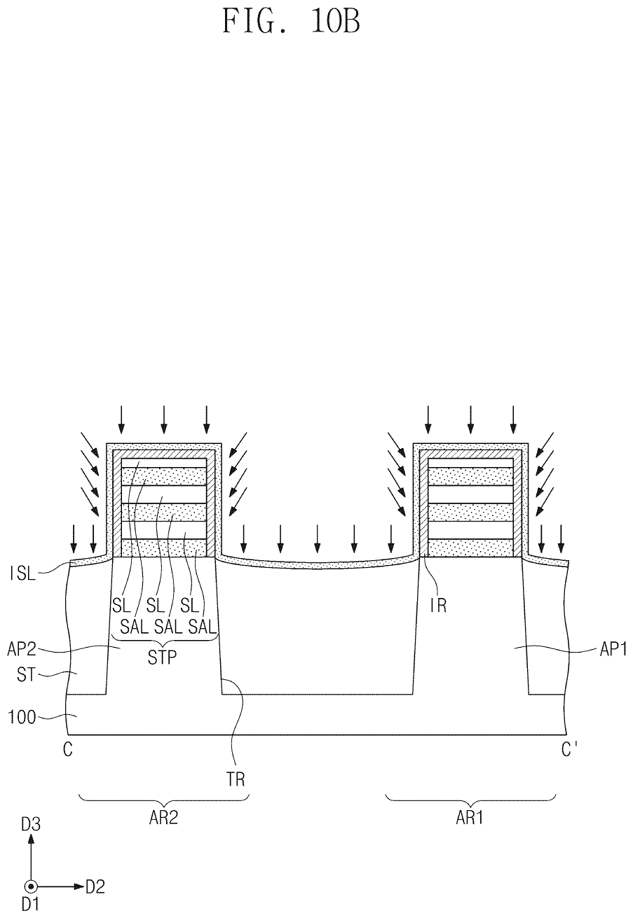

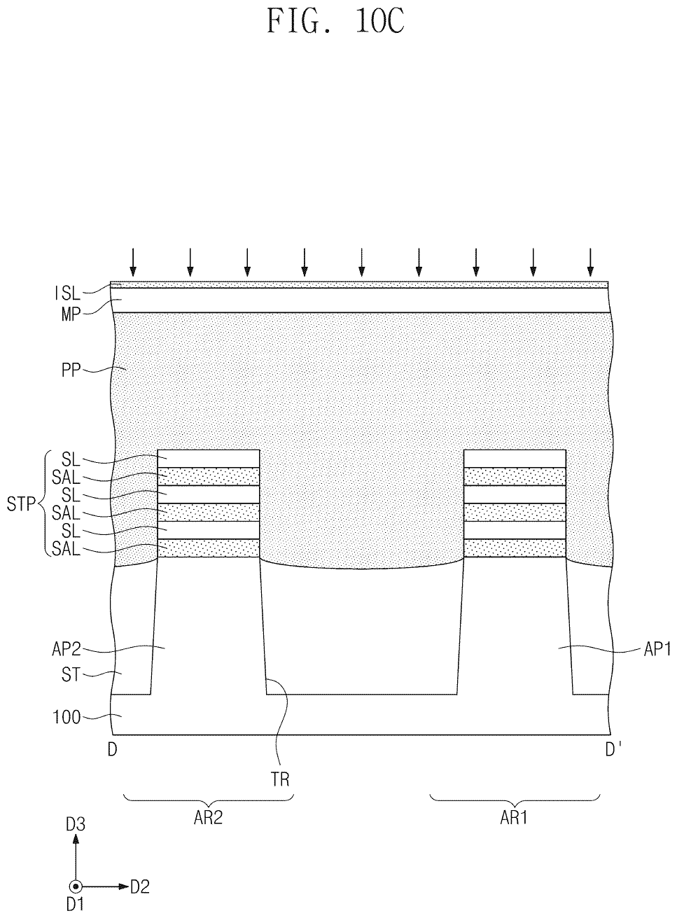

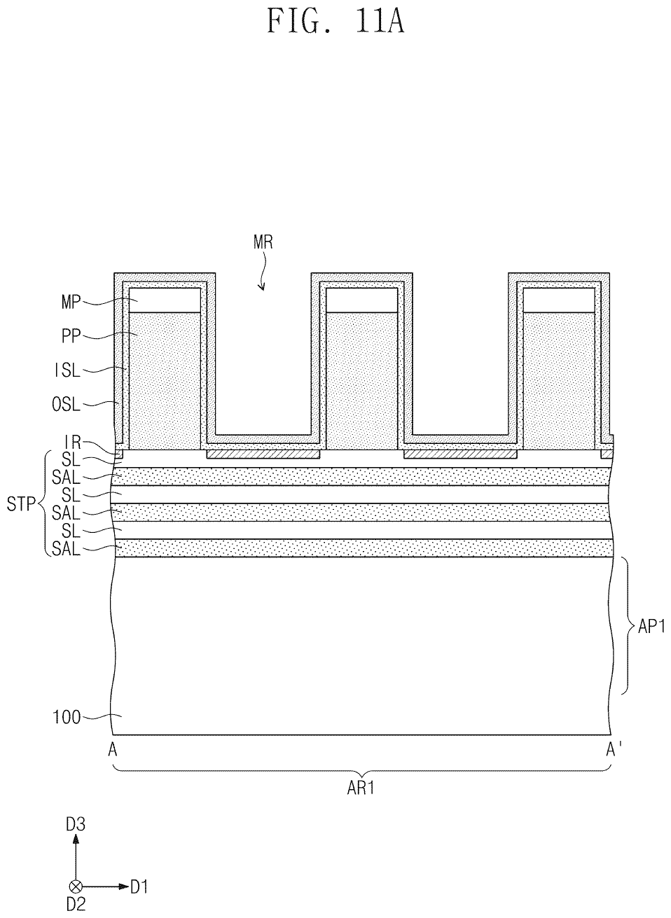

FIGS. 9A to 14C are cross-sectional views illustrating a method of manufacturing a semiconductor device according to various example embodiments. Hereinafter, a method of manufacturing a semiconductor device according to various example embodiments will be described with reference to FIGS. 1 and 9A to 14C. For simplification of the description, a description of the content overlapping with the above-described content will be omitted.

Referring to FIGS. 1, 9A, and 9B, a substrate 100 including first and second active regions AR1 and AR2 may be provided. A stacked pattern STP including alternately stacked semiconductor layers SL and sacrificial layers SAL may be formed on the substrate 100. The stacked pattern STP may be formed in plurality, and the stacked patterns STP may be provided on the first and second active regions AR1 and AR2, respectively. The stacked pattern STP may extend in a first direction D1.

Forming the stacked pattern STP may include alternately stacking the semiconductor layers SL and the sacrificial layers SAL on the substrate 100 (e.g., with an atomic layer deposition (ALD) process), forming mask patterns (not shown) extending in the first direction D1 after stacking, and performing a patterning process on the mask patterns as an etch mask. Through the patterning process, the stacked patterns STP having a shape of the mask patterns may be formed, and a portion of the substrate 100 may be etched together to form a trench TR. The first and second active patterns AP1 and AP2 may be defined by the trench TR in the first and second active regions AR1 and AR2, respectively.

The semiconductor layers SL may be or may include one of silicon (Si), germanium (Ge), and silicon-germanium (SiGe), and the sacrificial layers SAL may include another one of silicon (Si), germanium (Ge), and silicon-germanium (SiGe) that is different from the semiconductor layers SL, and may or may not be lightly doped with impurities such as boron.

The sacrificial layers SAL may include a material having an etch selectivity with respect to the semiconductor layers SL. For example, the semiconductor layers SL may include silicon (Si), and the sacrificial layers SAL may include silicon-germanium (SiGe). For example, a concentration of germanium (Ge) in each of the sacrificial layers SAL may be 10 at % to 30 at %.

Thereafter, a device isolation pattern ST may be formed to fill the trench TR. Forming the device isolation pattern ST may include forming a device isolation layer (not shown) filling the trench TR and covering the stacked patterns STP, and separating the device isolation layer into the device isolation patterns ST by recessing the device isolation layer below the stacked patterns STP. The device isolation pattern ST may include an insulating material (e.g., silicon oxide). The stacked patterns STP may protrude vertically above the device isolation pattern ST.

Referring to FIGS. 1 and 10A to 10C, sacrificial patterns PP may be formed to cross the stacked patterns STP in a second direction D2 on the substrate 100. Each of the sacrificial patterns PP may be formed in a line shape or a bar shape extending in the second direction D2.

Forming the sacrificial patterns PP may include forming a sacrificial material layer (not shown) on the entire surface of the substrate 100, forming hard mask patterns MP on the sacrificial material layer, and patterning the sacrificial layer by using the hard mask patterns MP as an etch mask. Through the patterning process, the sacrificial patterns PP having a shape of the hard mask patterns MP may be formed. The sacrificial patterns PP may include polysilicon.

While forming the sacrificial patterns PP, mask recesses MR may be formed. The mask recesses MR may be formed between the sacrificial patterns PP. The mask recesses MR may expose a portion of an upper surface of the stacked pattern STP. The mask recesses MR may be defined by side surfaces of the sacrificial patterns PP, side surfaces of the hard mask patterns MP, and an exposed upper surface of the stacked pattern STP. Inner spacer layer ISL may be formed, e.g. formed with a process such as a chemical vapor deposition CVD) process, to conformally cover inner walls of the mask recesses MR and upper surfaces of the hard mask patterns MP. The inner spacer layer ISL may partially fill the inside of the mask recesses MR. For example, the inner spacer layer ISL may directly cover a portion of the stacking pattern STP in a region where the mask recesses MR are formed. The inner spacer layer ISL may include, for example, at least one of SiON, SiCN, SiOCN, and SiN.

Thereafter, an ion implantation process may be performed on the inner spacer layer ISL. The ion implantation process may be performed using ions of a group IV element, for example, one or more of carbon ions, silicon ions, or germanium ions. The ions may pass through the inner spacer layer ISL and be implanted to a partial region of the stacked pattern STP directly covered by the inner spacer layer ISL. The partial region of the ion-implanted stacked pattern STP may be defined as an ion-implanted region IR.

The ion-implanted region IR may have an etch rate that is different from an etch rate of other regions of the stacked pattern STP in which ions are not implanted, in the subsequent etching process. For example, the etch rate of the ion-implanted region IR may be faster than the etch rate of other regions.

The ion implantation process may proceed in various directions. For example, ions may be implanted in a direction perpendicular to a plane into which the ions are implanted, and may be an anisotropic ion implantation process. Alternatively or additionally, ions may be implanted in a direction oblique to the plane into which the ions are implanted. By adjusting the ion implantation direction, a size and/or depth of the ion-implanted region may be adjusted. A size and/or a depth of the ion-implanted region may be determined, e.g. may be based on, a dose and/or an energy of the ion implantation process. For example, the ion implantation process may be performed on the entire surface of the substrate. Alternatively, the ion implantation process may be performed locally on only a portion of the substrate.

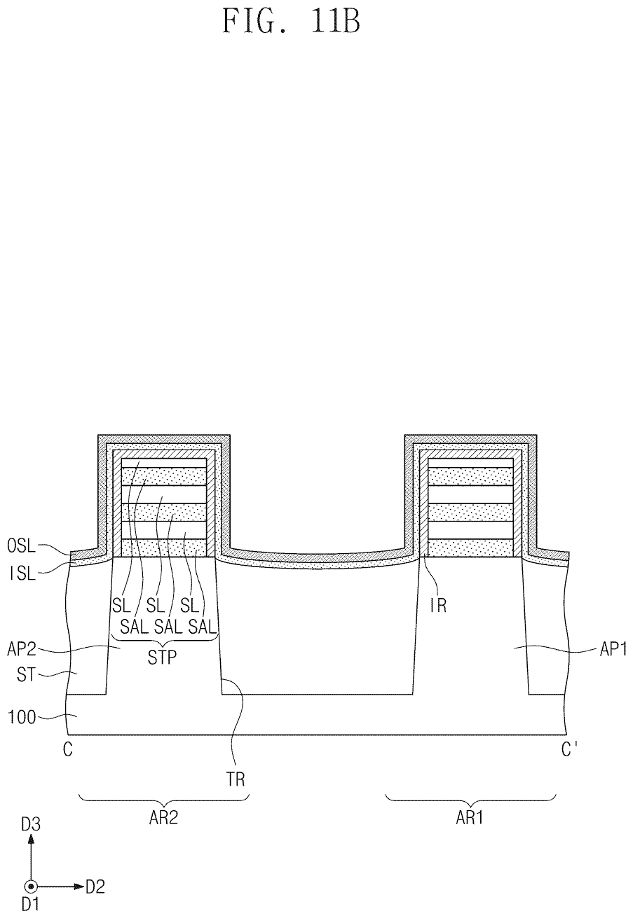

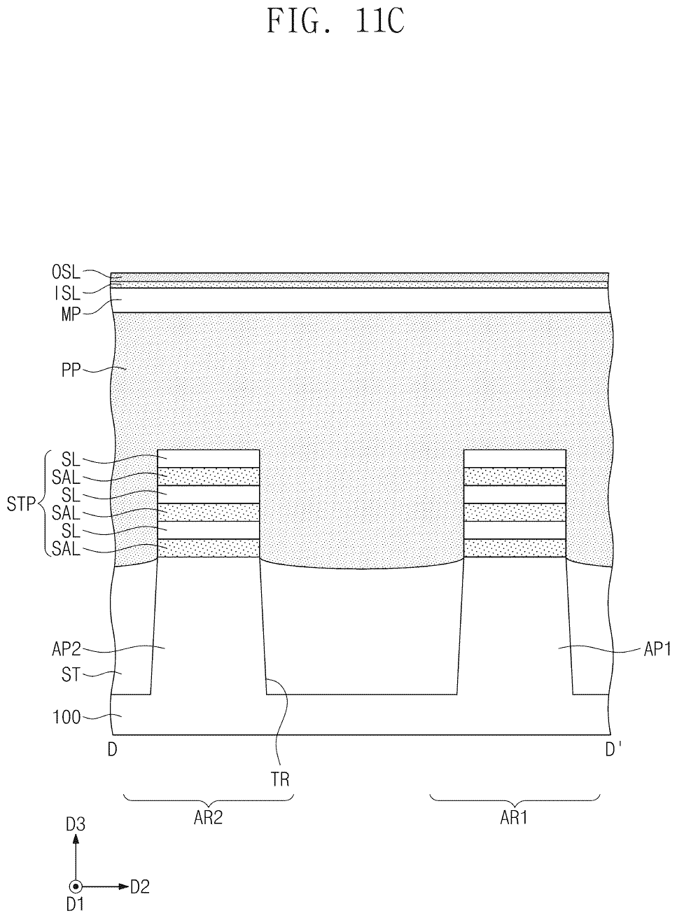

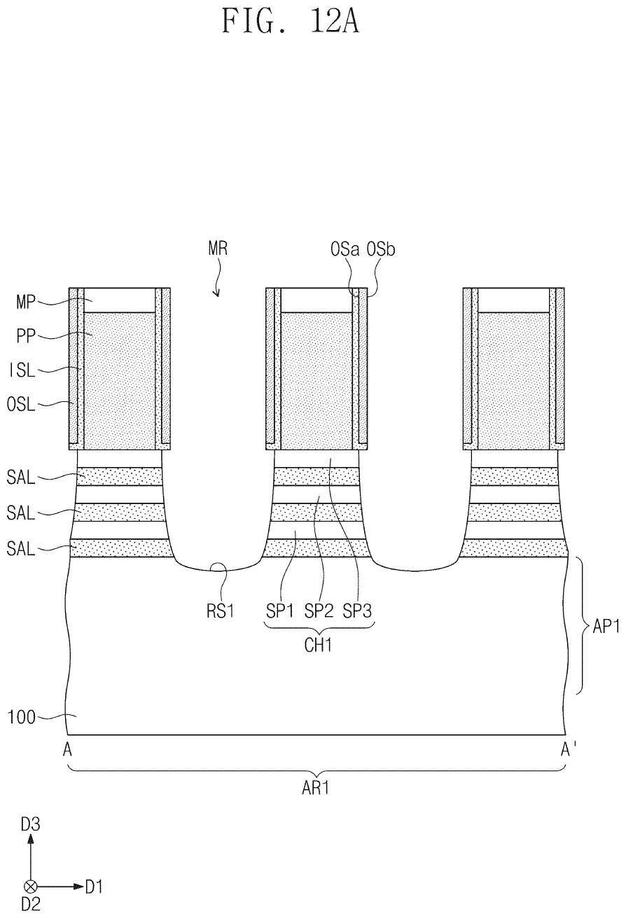

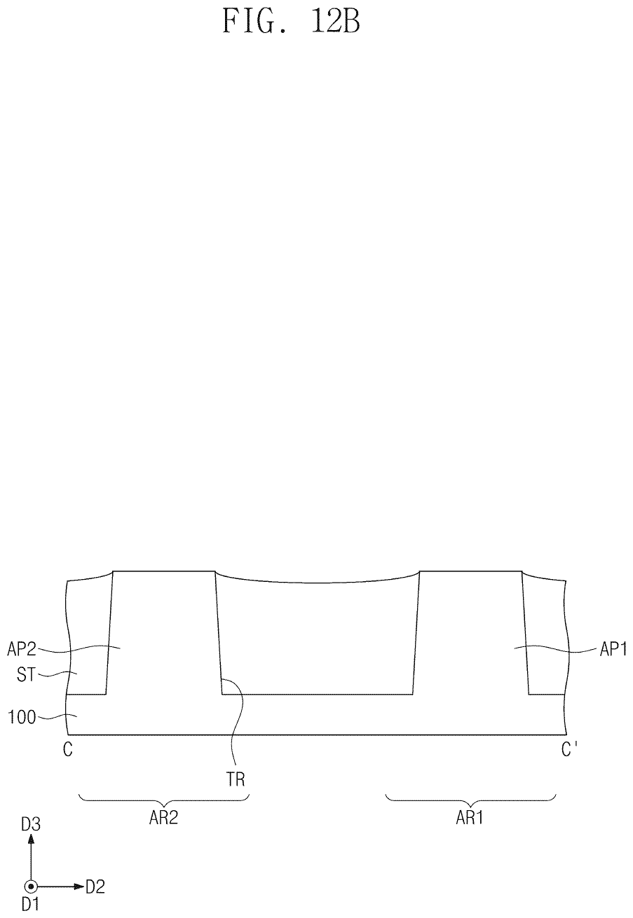

For convenience of explanation, FIG. 10A shows only a cross section corresponding to A-A′ of FIG. 1, but the same manufacturing method may be performed on a cross-section corresponding to B-B′ of FIG. 1. For example, the above processes may be simultaneously performed in a region corresponding to A-A′ of FIG. 1 and a region corresponding to B-B′ of FIG. 1. As another example, in the region corresponding to A-A′ of FIG. 1 and the region corresponding to B-B′ of FIG. 1, the processes may be separately performed. For convenience of explanation, hereinafter, the manufacturing method will be described with reference to A-A′ of FIG. 1 in FIGS. 11A to 13A, but substantially the same manufacturing method may be performed simultaneously or sequentially in the region corresponding to B-B′ in FIG. 1.

Referring to FIGS. 1 and 11A to 11C, outer spacer layer OSL may be formed to conformally cover the inner spacer layer ISL. The outer spacer layer OSL may cover inner walls of the mask recesses MR and upper surfaces of the hard mask patterns MP on the inner spacer layer ISL. The outer spacer layer OSL may partially fill the inside of the mask recesses MR. The outer spacer layer OSL may cover the ion-implanted region IR, and may be spaced apart from the ion-implanted region IR by the inner spacer layer ISL. The outer spacer layer OSL may include, for example, at least one of SiON, SiCN, SiOCN, and SiN.

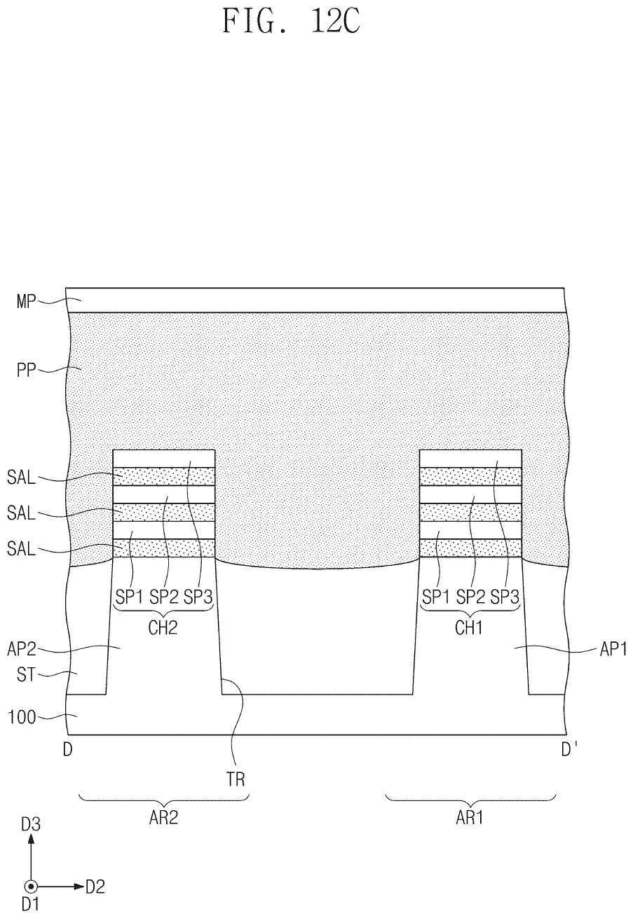

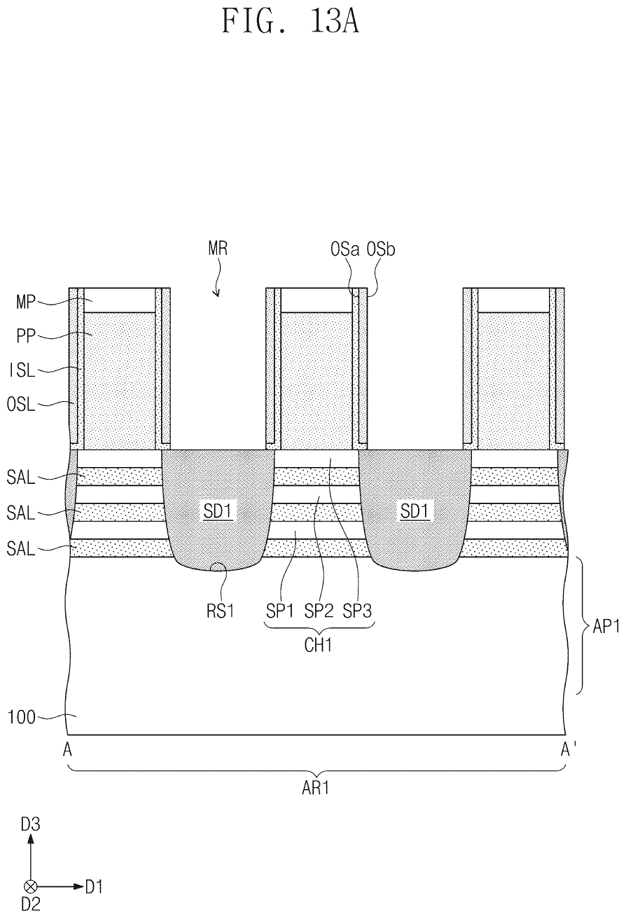

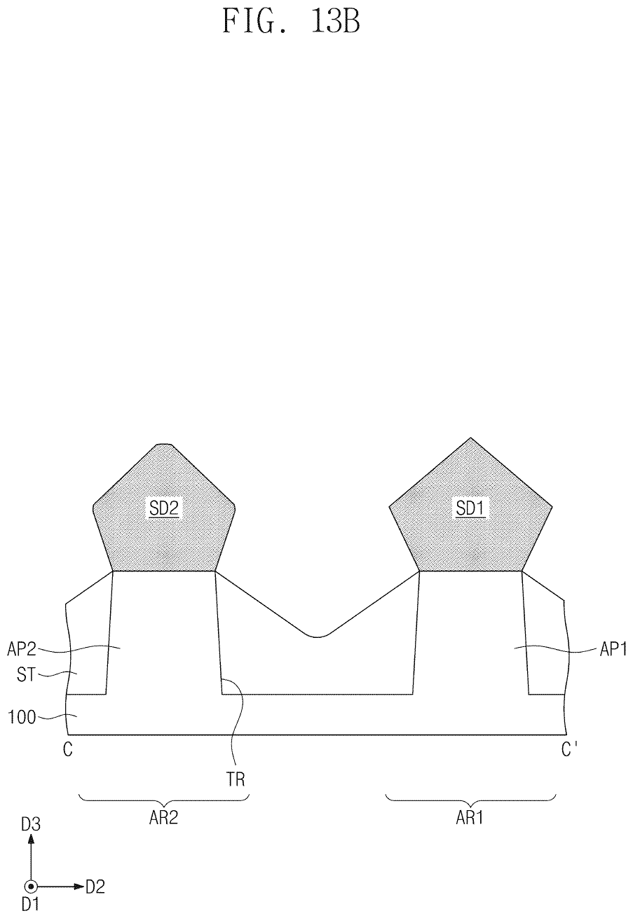

Referring to FIGS. 1 and 12A to 12C, inner spacers IS and outer spacers OS may be formed by etching the inner and outer spacer layers ISL and OSL. The etching process may be an anisotropic etching process. Through the etching process, the inner and outer spacer layers ISL and OSL may be removed from the hard mask patterns MP and from inner lower walls of the mask recesses MR, and may be separated into the inner and outer spacers IS and OS. Through the etching process, upper surfaces of the hard mask patterns MP and inner lower walls of the mask recesses MR (e.g., the ion-implanted region IR of the stacked pattern STP) may be exposed.

Thereafter, first recesses RS1 may be formed in the stacking pattern STP. The first recesses RS1 may be formed under the mask recess MR. Forming the first recesses RS1 may include etching the stacked pattern STP using the hard mask patterns MP, the inner spacers IS, and the outer spacers OS as an etch mask. The first recesses RS1 may be formed between the pair of sacrificial patterns PP.

The first recesses RS1 may expose at least a portion of lower surfaces of the inner spacers IS. A width of an upper end of each of the first recesses RS1 in the first direction D1 at a first level LV1 may be greater than a distance between the outer spacers OS opposite to each other with the mask recess MR interposed therebetween.

In forming the first recesses RS1, upper portions of the first recesses RS1 may be easily widened in the first direction D1 due to the ion-implanted region IR. That is, the etch rate of the ion-implanted region IR may be faster than the etch rate of other regions of the stacked pattern STP, and thus the ion-implanted region IR may be etched relatively easily. For example, the first recesses RS1 may be formed widely in the region where the ion-implanted region IR is formed, and the upper portions of the first recesses RS1 may be formed below the inner and outer spacers IS and OS. In this case, it may be prevented or reduced in probability or impact from the upper portions of the first recesses RS1 being formed to be relatively narrow and the lower portions are formed to be relatively wide, and rounding of a side profile of the first source/drain pattern SD1 in a subsequent process may be reduced or minimized Accordingly, a distribution of positions where the first source/drain pattern SD1 and first to third semiconductor patterns SP1, SP2, and SP3 are connected may be improved, and as a result, electrical characteristics and/or a reliability of the semiconductor device may be improved.

Alternatively or additionally, a difference between a first width W1 and a second width W2 of FIGS. 3A and 3B may also be reduced or minimized by adjusting the etching rate through the ion implantation process. As a result, the distribution of the positions where the first source/drain pattern SD1 and first channel patterns CH1 (i.e., the first to third semiconductor patterns SP1, SP2, and SP3) are connected may be improved, and as a result, the electrical characteristics and/or reliability of the semiconductor device may be improved.

The semiconductor layers SL of the stacked pattern STP may be separated into first channel patterns CH1 by the first recesses RS1. The first channel patterns CH1 may include first to third semiconductor patterns SP1, SP2, and SP3, respectively. In this case, an upper portion of the device isolation pattern ST that is not covered with the sacrificial patterns PP may be further recessed.

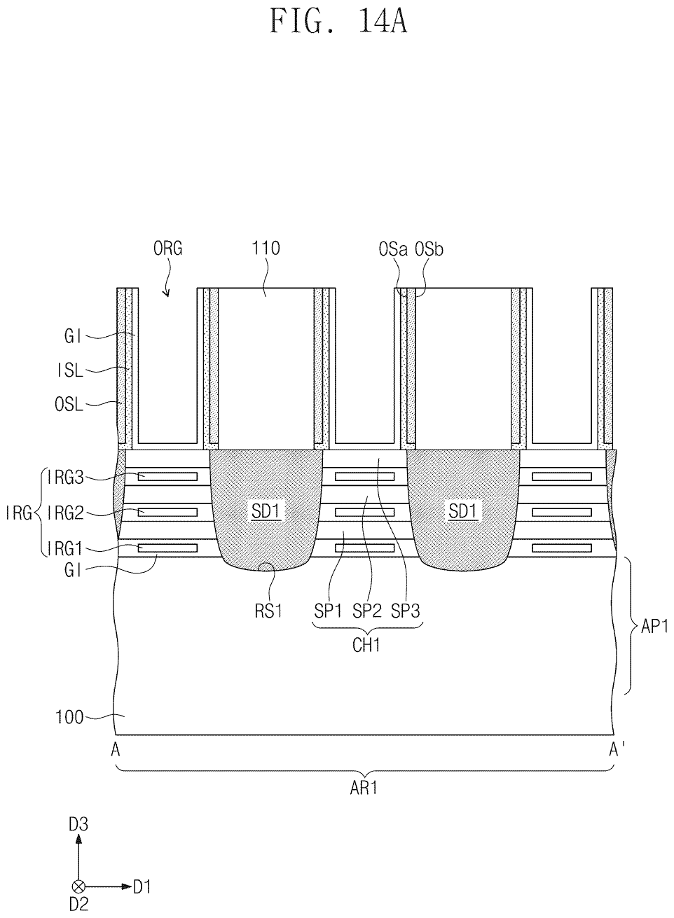

Referring to FIGS. 1, 13A, and 13B, first source/drain patterns SD1 may be respectively formed in the first recesses RS1. The first source/drain patterns SD1 may be epitaxial layers formed by performing an SEG process using inner surfaces of the first recesses RS1 as a seed layer. The epitaxial layer may be grown using the first to third semiconductor patterns SP1, SP2, and SP3 exposed by the first recesses RS1 and the substrate 100 as seeds. For example, the SEG process may include a chemical vapor deposition (CVD) process and/or a molecular beam epitaxy (MBE) process.

For example, while the first source/drain pattern SD1 is formed, impurities (e.g., one or more of boron, gallium, or indium) that cause the first source/drain pattern SD1 to have a p-type may be injected in-situ. As another example, after the first source/drain pattern SD1 is formed, impurities may be implanted into the first source/drain pattern SD1.

As described above, second source/drain patterns SD2 may be respectively formed in second recesses RS2 through a manufacturing method similar to that of the first source/drain patterns SD1. The second source/drain patterns SD2 may be epitaxial layers formed by performing an SEG process using inner surfaces of the second recesses RS2 as a seed layer.

For example, while the second source/drain pattern SD2 is formed, impurities (e.g., one or more of phosphorus, arsenic, or antimony) that cause the second source/drain pattern SD2 to have an n-type may be injected or incorporated in-situ. Alternatively or additionally, after the second source/drain pattern SD2 is formed, impurities may be implanted into the second source/drain pattern SD2.

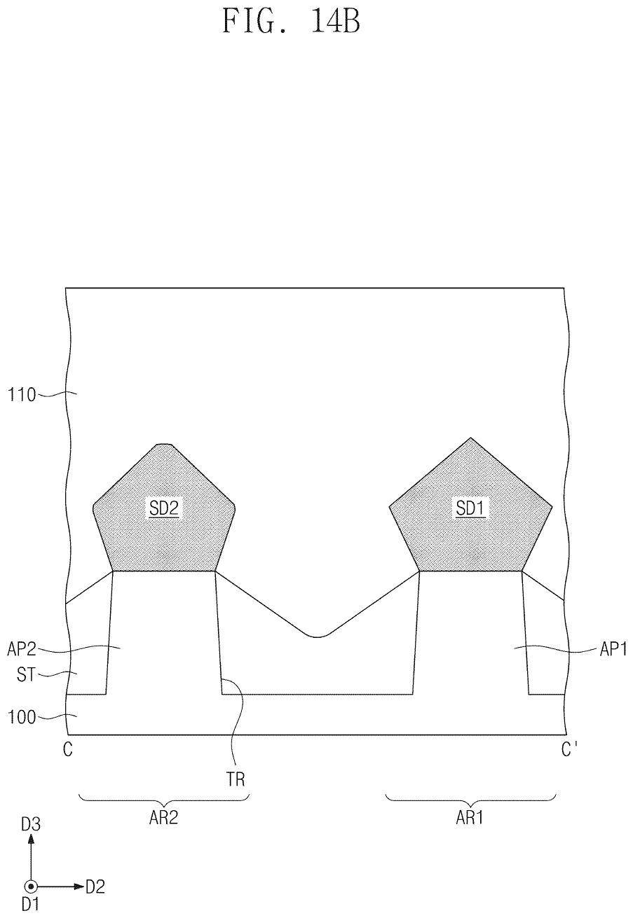

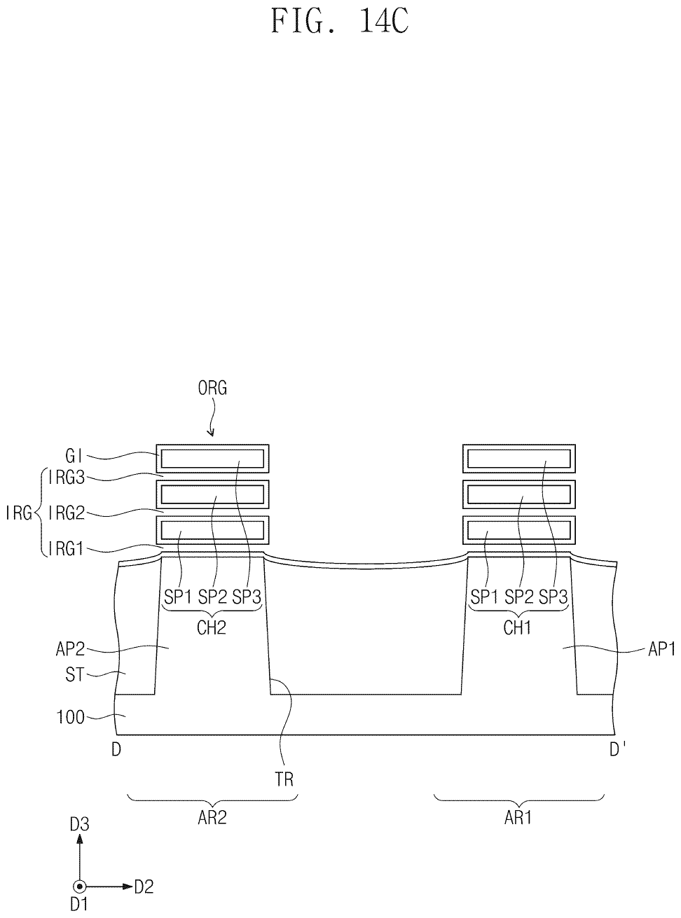

Referring to FIGS. 1 and 14A to 14C, a first interlayer insulating layer 110 may be formed to cover the first and second source/drain patterns SD1 and SD2, the hard mask patterns MP, and the first and outer spacers IS and OS. For example, the first interlayer insulating layer 110 may include silicon oxide.

The first interlayer insulating layer 110 may be planarized until upper surfaces of the sacrificial patterns PP are exposed. The planarization may be performed using an etch-back or chemical mechanical polishing (CMP) process. During the planarization process, all of the hard mask patterns MP may be removed. As a result, an upper surface of the first interlayer insulating layer 110 may be coplanar with upper surfaces of the sacrificial patterns PP and upper surfaces of the inner and outer spacers IS and OS.

The exposed sacrificial patterns PP may be selectively removed. As the sacrificial patterns PP are removed, an outer region ORG exposing the first and second channel patterns CH1 and CH2 may be formed. Removing the sacrificial patterns PP may include wet etching using an etchant that selectively etches polysilicon.

The sacrificial layers SAL exposed through the outer region ORG may be selectively removed, thereby forming inner regions IRG. The inner regions IRG may include, for example, first to third inner regions IRG1, IRG2, and IRG3 spaced apart from each other in a third direction D3. In this case, the first to third semiconductor patterns SP1, SP2, SP3 and a buffer layer BL may remain unetched due to a high etch selectivity of the sacrificial layers SAL. The etching process may be wet etching. The first to third semiconductor patterns SP1, SP2, and SP3 may be exposed through the outer region ORG and the inner regions IRG.

A gate insulating pattern GI may be formed on the exposed first to third semiconductor patterns SP1, SP2, and SP3. The gate insulating pattern GI may be formed to surround each of the first to third semiconductor patterns SP1, SP2, and SP3. The gate insulating pattern GI may be formed in each of the inner regions IRG and the outer region ORG.

Referring back to FIGS. 1 and 2A to 2D, a gate electrode GE may be formed on the gate insulating pattern GI. The gate electrode GE may include first to third electrode parts EP1, EP2, and EP3 formed in each of the first to third inner regions IRG1, IRG2, and IRG3 and a fourth electrode part EP4 formed in the outer region ORG may be included. The fourth electrode part EP4 may have a recessed upper portion, and thus may have a lower height than upper surfaces of the inner and outer spacers IS and OS. A gate capping pattern GC may be formed on the recessed fourth electrode part EP4.

A second interlayer insulating layer 120 may be formed on the first interlayer insulating layer 110 and the gate capping pattern GC. The second interlayer insulating layer 120 may include silicon oxide. An active contacts AC may pass through the first and second interlayer insulating layers 110 and 120 to be connected to each of the first and second source/drain patterns SD1 and SD2. Forming the active contacts AC may include forming a barrier pattern BM and forming a conductive pattern CP on the barrier pattern BM. The barrier pattern BM may be conformally formed. An ohmic pattern OM may be further formed between the active contacts AC and corresponding source/drain patterns SD1 and SD2.

A third interlayer insulating layer 130 may be formed on the second interlayer insulating layer 120 and the active contacts AC. The third interlayer insulating layer 130 may include silicon oxide. Metal patterns MT and vias VIA may be formed in the third interlayer insulating layer 130.

According to the inventive concept, the dispersion of the positions where the source/drain patterns and the channel patterns are connected may be improved. As a result, the electrical characteristics and reliability of the semiconductor device may be improved. When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Moreover, when the words “generally” and “substantially” are used in connection with material composition, it is intended that exactitude of the material is not required but that latitude for the material is within the scope of the disclosure.

Further, regardless of whether numerical values or shapes are modified as “about” or “substantially,” it will be understood that these values and shapes should be construed as including a manufacturing or operational tolerance (e.g., ±10%) around the stated numerical values or shapes. Thus, while the term “same,” “identical,” or “equal” is used in description of example embodiments, it should be understood that some imprecisions may exist. Thus, when one element or one numerical value is referred to as being the same as another element or equal to another numerical value, it should be understood that an element or a numerical value is the same as another element or another numerical value within a desired manufacturing or operational tolerance range (e.g., ±10%).

While various example embodiments are described above, a person of ordinary skill in the art may understand that many modifications and variations are made without departing from the spirit and scope of example embodiments defined in the following claims. Accordingly, various example embodiments of inventive concepts should be considered in all respects as illustrative and not restrictive, with the spirit and scope of inventive concept being indicated by the appended claims. Furthermore example embodiments are not necessarily mutually exclusive with one another. For example, some example embodiments may include one or more features described with reference to one or more figures, and may also include one or more features described with reference to one or more other figures.

What is claimed is:

1. A semiconductor device comprising:
a substrate including an active pattern;
a pair of channel patterns spaced apart from each other in a first direction on the active pattern, each of the pair of channel patterns including vertically stacked semiconductor patterns;
a source/drain pattern between the pair of channel patterns;
a pair of gate electrodes on the pair of channel patterns;
an active contact between the pair of gate electrodes; and
outer spacers on side surfaces of the pair of gate electrodes,
wherein a distance between the outer spacers spaced apart from each other with the active contact therebetween is smaller than a width of the source/drain pattern along the first direction at a first level at which an upper surface of an uppermost semiconductor pattern among the semiconductor patterns is positioned.

2. The semiconductor device of claim 1, wherein a portion of the source/drain pattern at the first level at least partially vertically overlaps the outer spacers.

3. The semiconductor device of claim 1, wherein an upper surface of the source/drain pattern includes edge surfaces under the outer spacers, and
the outer spacers are vertically spaced apart from the source/drain pattern.

4. The semiconductor device of claim 1, wherein a width of the source/drain pattern in the first direction at the first level is greater than at other levels.

5. The semiconductor device of claim 1, wherein
a width of the source/drain pattern in the first direction at a second level is larger than at other levels, and
the second level is a level between an upper surface and a lower surface of an uppermost layer of the semiconductor patterns.

6. The semiconductor device of claim 1, wherein
the semiconductor patterns are vertically spaced apart from each other,
each of the pair of gate electrodes are interposed respectively between the semiconductor patterns of the pair of channel patterns, and
the source/drain pattern includes protrusions which protrude toward the pair of gate electrodes respectively between the pair of channel patterns.

7. The semiconductor device of claim 1, wherein
the semiconductor patterns are vertically spaced apart from each other,
each of the pair of gate electrodes are interposed respectively between the semiconductor patterns of the pair of channel patterns, and
the semiconductor device further includes horizontal insulating patterns interposed between the semiconductor patterns, and between the source/drain patterns and the gate electrodes.

8. The semiconductor device of claim 1, further comprising:
inner spacers between side surfaces of the pair of gate electrodes and the outer spacers,
wherein each of the inner spacers includes a corner part which extends between lower surfaces of the outer spacers and the source/drain pattern.

9. The semiconductor device of claim 8, wherein a portion of the source/drain pattern at the first level at least partially vertically overlaps the corner part.

10. The semiconductor device of claim 8, wherein each of the outer spacers is spaced apart from the source/drain pattern by the corner part.

11. The semiconductor device of claim 8, wherein a distance between the corner parts spaced apart from each other with the active contact therebetween is smaller than a width of the source/drain pattern at the first level in the first direction.

12. The semiconductor device of claim 8, wherein
an upper surface of the source/drain pattern includes edge surfaces under the outer spacers, and
the edge surfaces are in contact with the inner spacers.

13. A semiconductor device comprising:
a substrate including an active pattern;
an isolation pattern surrounding the active pattern;
a pair of channel patterns spaced apart from each other in a first direction on the active pattern, each of the pair of channel patterns including vertically stacked semiconductor patterns;
a source/drain pattern between the pair of channel patterns;
a pair of gate electrodes on the pair of channel patterns;
gate capping patterns on upper surfaces of the pair of gate electrodes;
an interlayer insulating layer between the pair of gate electrodes;
outer spacers on side surfaces of the pair of gate electrodes;
inner spacers between the side surfaces of the pair of gate electrodes and the outer spacers;
gate insulating patterns between the pair of gate electrodes and the inner spacers; and
an active contact connected to the source/drain pattern through the interlayer insulating layer, wherein
the outer spacers and the inner spacers extend on side surfaces of the gate capping patterns, and
a distance between the outer spacers are spaced apart from each other with the active contact therebetween is smaller than a width of a source/drain pattern in the first direction at a first level at which an upper surface of an uppermost semiconductor pattern among the semiconductor patterns is positioned.

14. The semiconductor device of claim 13, wherein an upper surface of the source/drain pattern includes edge surfaces under the outer spacers.

15. The semiconductor device of claim 13, wherein the outer spacers are spaced apart from the source/drain pattern by the inner spacers.

16. A method of manufacturing a semiconductor device, the method comprising:
forming a stacked pattern on a substrate;
forming sacrificial patterns on the stacked pattern, hard mask patterns on upper surfaces of the sacrificial patterns, and mask recesses between the sacrificial patterns;
performing an ion implantation process after forming an inner spacer layer, the inner spacer layer conformally covering inner walls of the mask recesses;
forming an outer spacer layer which conformally covers the inner spacer layer;
etching the inner spacer layer and the outer spacer layer to form inner spacers and outer spacers, respectively;
etching the stacked pattern using the hard mask patterns, the inner spacers, and the outer spacers as an etch mask to form a recess; and
forming a source/drain pattern which fills the recess.

17. The method of claim 16, wherein the ion implantation process is performed using germanium ions.

18. The method of claim 16, wherein
the inner spacer layer directly covers a portion of the stacked pattern, and
an ion-implanted region is formed in the portion of the stacked pattern through the ion implantation process.

19. The method of claim 18, wherein, in the etching of the stacked pattern, an etching rate of the ion-implanted region of the stacked pattern is faster than an etching rate of other regions of the stacked pattern.

20. The method of claim 16, wherein the recess exposes at least a portion of lower surfaces of the inner spacers.
